(19) United States
(12) Patent Application Publication
(10) Pub. No.: US 2022/0376059 A1
(43) Pub. Date: Nov. 24, 2022

(54) SEMICONDUCTOR DEVICE STRUCTURES AND METHODS OF MANUFACTURING THE SAME

(71) Applicant: INNOSCIENCE (SUZHOU) SEMICONDUCTOR CO., LTD., Suzhou (CN)

(72) Inventors: King Yuen WONG, Zhuhai (CN); Peng-Yi WU, Zhuhai (CN)

(21) Appl. No.: 17/266,123

(22) PCT Filed: Dec. 28, 2020
(86) PCT No.: PCT/CN2020/140119

§ 371 Date: Feb. 5, 2021

(51) Int. Cl. H01L 29/40; H01L 29/778; H01L 29/66; H01L 29/20

(52) U.S. Cl. CPC H01L 29/402; H01L 29/7786; H01L 29/66462; H01L 29/2003; H01L 29/401

(57) ABSTRACT

Semiconductor device structures and methods for manufacturing the same are provided. The semiconductor device structure includes a substrate, a semiconductor layer on the substrate, and a patterned dielectric layer disposed on the substrate and covered by the semiconductor layer. The patterned dielectric layer is configured to prevent a constituent in the semiconductor layer from diffusing into the substrate. The semiconductor device structure further includes a first nitride semiconductor layer on the semiconductor layer and a second nitride semiconductor layer on the first nitride semiconductor layer. A band gap of the second nitride semiconductor layer is greater than a band gap of the first nitride semiconductor layer.

### BACKGROUND

### 1. Field of the Disclosure

The present disclosure relates to a semiconductor device structure and more particularly to a semiconductor device structure with a patterned dielectric layer.

### 2. Description of Related Art

Semiconductor device structures having direct bandgap semiconductors (e.g., semiconductor device structures having III-V materials) can operate or work under a variety of conditions, such as at different voltages and/or different frequencies.

The semiconductor device structures may include a heterojunction bipolar transistor (HBT), a heterojunction field effect transistor (HFET), a high-electron-mobility transistor (HEMT), a modulation-doped FET (MODFET), etc.

### SUMMARY

According to some embodiments of the present disclosure, a semiconductor device structure includes a substrate, a semiconductor layer on the substrate, and a patterned dielectric layer disposed on the substrate and covered by the semiconductor layer. The patterned dielectric layer is configured to prevent a constituent in the semiconductor layer from diffusing into the substrate. The semiconductor device structure further includes a first nitride semiconductor layer on the semiconductor layer and a second nitride semiconductor layer on the first nitride semiconductor layer. A band gap of the second nitride semiconductor layer is greater than a band gap of the first nitride semiconductor layer.

According to some embodiments of the present disclosure, a semiconductor device structure includes a substrate, a semiconductor layer on the substrate, and a patterned dielectric layer disposed on the substrate and covered by the semiconductor layer. A percentage of total area coverage of the patterned dielectric layer on the substrate is between about 50 percent (%) and about 85%. The semiconductor device structure further includes a first nitride semiconductor layer on the semiconductor layer and a second nitride semiconductor layer on the first nitride semiconductor layer. A band gap of the second nitride semiconductor layer is greater than a band gap of the first nitride semiconductor layer.

According to some embodiments of the present disclosure, a method of manufacturing a semiconductor device structure includes providing a substrate having a surface, depositing a dielectric layer on the surface of the substrate, and patterning the dielectric layer to form a plurality of vias through the dielectric layer. About 15% to about 50% of the surface of the substrate is exposed from the plurality of vias.

### BRIEF DESCRIPTION OF THE DRAWINGS

Aspects of the present disclosure are readily understood from the following detailed description when read with the accompanying figures. It should be noted that various features may not be drawn to scale. In fact, the dimensions of the various features may be arbitrarily increased or reduced for clarity of discussion.

FIG. 1 is a cross-sectional view of a semiconductor device structure in accordance with some embodiments of the present disclosure.

FIG. 2A is a cross-sectional view of a part of a semiconductor device structure in accordance with some embodiments of the present disclosure.

FIG. 2B is a cross-sectional view of a part of a semiconductor device structure in accordance with some embodiments of the present disclosure.

FIG. 3A is a top view of a part of a semiconductor device structure in accordance with some embodiments of the present disclosure.

FIG. 3B is a cross-sectional view of a part of a semiconductor device structure in accordance with some embodiments of the present disclosure.

FIG. 4A is a top view of a part of a semiconductor device structure in accordance with some embodiments of the present disclosure.

FIG. 4B is a cross-sectional view of a part of a semiconductor device structure in accordance with some embodiments of the present disclosure.

FIG. 5A is a top view of a part of a semiconductor device structure in accordance with some embodiments of the present disclosure.

FIG. 5B is a cross-sectional view of a part of a semiconductor device structure in accordance with some embodiments of the present disclosure.

FIG. 6A is a top view of a part of a semiconductor device structure in accordance with some embodiments of the present disclosure.

FIG. 6B is a cross-sectional view of a part of a semiconductor device structure in accordance with some embodiments of the present disclosure.

FIG. 7A is a top view of a part of a semiconductor device structure in accordance with some embodiments of the present disclosure.

FIG. 7B is a cross-sectional view of a part of a semiconductor device structure in accordance with some embodiments of the present disclosure.

FIG. 8A is a top view of a part of a semiconductor device structure in accordance with some embodiments of the present disclosure.

FIG. 8B is a cross-sectional view of a part of a semiconductor device structure in accordance with some embodiments of the present disclosure.

FIG. 9A, FIG. 9B, FIG. 9C, and FIG. 9D illustrate various stages of a method for manufacturing a semiconductor device structure in accordance with some embodiments of the present disclosure.

Common reference numerals are used throughout the drawings and the detailed description to indicate the same or similar components. The present disclosure will be more apparent from the following detailed description taken in conjunction with the accompanying drawings.

### DETAILED DESCRIPTION

The following disclosure provides many different embodiments, or examples, for implementing different features of the provided subject matter. Specific examples of components and arrangements are described below. These are, of course, merely examples and are not intended to be limiting. In the present disclosure, reference to the formation or disposal of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Embodiments of the present disclosure are discussed in detail as follows. It should be appreciated, however, that the present disclosure provides many applicable concepts that can be embodied in a wide variety of specific contexts. The specific embodiments discussed are merely illustrative and do not limit the scope of the disclosure.

The present disclosure provides a semiconductor device structure including multiple III-V group semiconductor layers formed on a substrate. The semiconductor device structure according to the present disclosure may be applied in, for example, but is not limited to, HEMT devices, such as low voltage HEMT devices, high voltage HEMT devices and radio frequency (RF) HEMT devices. The III-V group semiconductor layers may include, for example, but are not limited to, gallium arsenide (GaAs), indium phosphide (InP), gallium nitride (GaN), indium gallium arsenide (InGaAs), and aluminum gallium arsenide (InAlAs).

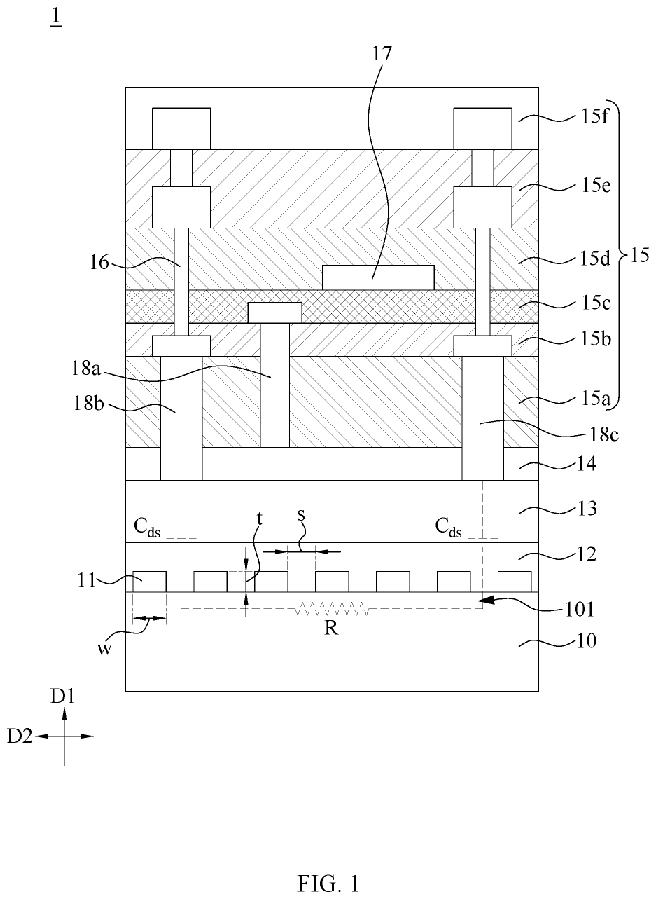

FIG. 1 is a cross-sectional view of a semiconductor device structure 1 in accordance with some embodiments of the present disclosure.

In some embodiments, the semiconductor device structure 1 may include a substrate 10, a patterned dielectric layer 11, a semiconductor layer 12, a nitride semiconductor layer 13, a nitride semiconductor layer 14, passivation layers 15a, 15b, 15c, 15d, 15e, 15f (which may be collectively referred to as the passivation layer 15), conductive structures 16, 18a, 18b, 18c, and a field plate 17.

The substrate 10 may include, for example, but is not limited to, silicon (Si), doped Si, silicon carbide (SiC), germanium silicide (SiGe), gallium arsenide (GaAs), or other semiconductor materials. The substrate 10 may include, for example, but is not limited to, sapphire (Al₂O₃), silicon on insulator (SOI), or other suitable materials. In some embodiments, the substrate 10 may include a p-type semiconductor material. The substrate 10 may include a p-type semiconductor material having a doping concentration of about 10¹⁷ atoms/cm³ to about 10²¹ atoms/cm³. The substrate 10 may include a p-type semiconductor material having a doping concentration of about 10¹⁹ atoms/cm³ to about 10²¹ atoms/cm³. The substrate 10 may include a p-type semiconductor material having a doping concentration of about 10²⁰ atoms/cm³ to about 10²¹ atoms/cm³. In some embodiments, the substrate 10 may include a p-type doped silicon layer. In some embodiments, the substrate 10 may include a silicon layer doped with arsenic (As). In some embodiments, the substrate 10 may include a silicon layer doped with phosphorus (P). In some embodiments, the substrate 10 may include an n-type semiconductor material. The substrate 10 may include an n-type semiconductor material having a doping concentration of about 10¹⁷ atoms/cm³ to about 10²¹ atoms/cm³. The substrate 10 may include an n-type semiconductor material having a doping concentration of about 10¹⁹ atoms/cm³ to about 10²¹ atoms/cm³. The substrate 10 may include an n-type semiconductor material having a doping concentration of about 10²⁰ atoms/cm³ to about 10²¹ atoms/cm³. In some embodiments, the substrate 10 may include an n-type doped silicon layer. In some embodiments, the substrate 10 may include a silicon layer doped with boron (B). In some embodiments, the substrate 10 may include a silicon layer doped with gallium (Ga).

The patterned dielectric layer 11 may be disposed on a surface 101 of the substrate 10. The patterned dielectric layer 11 may be in contact with the surface 101 of the substrate 10. The patterned dielectric layer 11 may include a plurality of sublayers or islands separate from each other. For example, two adjacent sublayers or islands are spaced apart from each other. For example, there is a gap or a distance between two adjacent sublayers or islands. In some embodiments, the patterned dielectric layer 11 may have any number of sublayers depending on the design requirements.

The percentage of total area coverage of the patterned dielectric layer 11 on the surface 101 of the substrate 10 may be between about 50 percent (%) and about 85%, such as about 55%, about 60%, about 65%, about 70%, about 75%, or about 80%. For example, about 50% to about 85% of the surface 101 of the substrate 10 may be covered by the patterned dielectric layer 11. In other words, about 15% to about 50% of the surface 101 of the substrate 10 may be exposed from the patterned dielectric layer 11. About 15% to about 50% of the surface 101 of the substrate 10 may be in contact with the semiconductor layer 12. In some embodiments, the percentage of total area coverage of the patterned dielectric layer 11 may affect the ability of the patterned dielectric layer 11 to block or prevent a constituent or constituents in the semiconductor layer 12 from diffusing into the substrate 10. For example, a greater percentage of total area coverage may introduce a better blocking ability. Experiments shows that the patterned dielectric layer 11 with a percentage of total area coverage exceeding about 50% may have a desired blocking ability. However, a greater percentage of total area coverage may result in a trade-off in the crystal quality of the semiconductor layer 12. For example, the semiconductor layer 12 grown on the patterned dielectric layer 11 with a percentage of total area coverage exceeding about 85% may have a relative long distance of lateral growth, which may undesirably affect the crystallization of the semiconductor layer 12. Therefore, the percentage of total area coverage of the patterned dielectric layer 11 is set to be between about 50% and about 85%.

A direction D1 (which can also be referred to as a first direction or a stacking direction) is substantially perpendicular to the surface 101 of the substrate 10. A direction D2 (which can also be referred to as a second direction) is substantially perpendicular to the direction D1. The patterned dielectric layer 11 may include a thickness (annotated as “t” in FIG. 1) measured in a direction perpendicular to the surface 101 (such as measured in the direction D1). The thickness t may range between about 0.5 micrometers (μm) and about 2.0 μm, such as 0.8 μm, 1.0 μm, 1.2 μm, 1.5 μm, or 1.8 μm.

Each of the sublayers of the patterned dielectric layer 11 may include a width (annotated as “w” in FIG. 1) measured in a direction parallel to the surface 101 (such as measured in the direction D2). The width w may range between about 0.5 μm and about 1.0 μm, such as 0.6 μm, 0.7 μm, 0.8 μm, or 0.9 μm.

Each of the sublayers of the patterned dielectric layer 11 may be separated from the adjacent sublayers by a spacing (annotated as “s” in FIG. 1) measured in a direction parallel to the surface 101 (such as measured in the direction D2). The spacing s may range between about 1.0 μm and about 3.0 μm, between about 1.0 μm and about 2.0 μm, or between about 1.0 μm and about 1.5 μm.

The numerical values mentioned above are for illustrative purposes only, and the present disclosure is not limited thereto. For example, the thickness t, the width w, and/or the spacing s may be adjusted depending on design requirements. In some embodiments, the thickness t, the width w, and/or the spacing s may be adjusted while staying within the range of the percentage of the total area coverage of the patterned dielectric layer 11 that can prevent a constituent or constituents in the semiconductor layer 12 from diffusing into the substrate 10.

The patterned dielectric layer 11 may include, for example, but is not limited to, an amorphous dielectric material, such as silicon nitride, silicon oxide and silicon oxynitride.

The semiconductor layer 12 may be disposed on the substrate 10. The semiconductor layer 12 may cover the patterned dielectric layer 11. The semiconductor layer 12 is disposed within the spacing s of two adjacent sublayers. The semiconductor layer 12 may be in contact with the portions of the substrate 10 that are exposed from the patterned dielectric layer 11.

The semiconductor layer 12 may include a multilayer structure. The semiconductor layer 12 may include a single layer structure. The semiconductor layer 12 may include, for example, but is not limited to, Al_{X}Ga_{(1-X)}N. In some embodiments, 0.5≤X≤1. In some embodiments, the semiconductor layer 12 may simply be AlN. In some embodiments, the semiconductor layer 12 may simply be GaN. In some embodiments, the semiconductor layer 12 may include a graded layer having increasing concentrations of Ga and decreasing concentrations of Al from the substrate 10 side to the nitride semiconductor layer 13 side. In some embodiments, the semiconductor layer 12 may include a superlattice layer having alternating AlGaN layers and AlN layers. The concentration variation of the superlattice layer may be gradual or stepwise in several layers.

The semiconductor layer 12 may function as a buffer layer between the substrate 10 and the nitride semiconductor layer 13 to prevent defects (such as cracks or dislocations) from propagating between the substrate 10 and the nitride semiconductor layer 13. In addition, since the semiconductor layer 12 may have an intermediate value coefficient of thermal expansion (CTE) with respect to the substrate 10 and the nitride semiconductor layer 13, the semiconductor layer 12 may reduce the degree of the CTE mismatch between the two layers, and thus reduce the mechanical stress therebetween.

The semiconductor layer 12 may be formed by epitaxial growth technique. In some embodiments, the epitaxial growth temperature may be about 1000 to about 1200 degrees Celsius (° C.), such as about 1010° C., about 1020° C., about 1030° C., about 1040° C., about 1050° C., about 1060° C., about 1070° C., about 1080° C., about 1090° C., about 1100° C., about 1110° C., about 1120° C., about 1130° C., about 1140° C., about 1150° C., about 1160° C., about 1170° C., about 1180° C., and about 1190° C. In comparison with a semiconductor layer formed under a relatively low epitaxial growth temperature (such as under a temperature lower than about 1000° C.), the semiconductor layer 12 formed under a relatively high epitaxial growth temperature (such as under a temperature higher than about 1000° C.) may be relatively free of defects (such as having fewer dislocations or cracks).

In some embodiments, the patterned dielectric layer 11 may be omitted. For example, the entire surface area of the surface 101 of the substrate 10 is in contact with the semiconductor layer 12. To obtain a relatively high quality semiconductor layer 12, a relatively high epitaxial growth temperature may be chosen. However, a relatively high epitaxial growth temperature may cause constituent or constituents in the semiconductor layer 12 to diffuse. For example, Al in the semiconductor layer 12 may diffuse into the substrate 10 as an acceptor, which may lower the parasitic resistance of the substrate 10 and cause a transmission loss in the substrate. In some embodiments, without the patterned dielectric layer 11, the diffusion depth of Al in the substrate 10 may be greater than about 10 nanometers (nm).

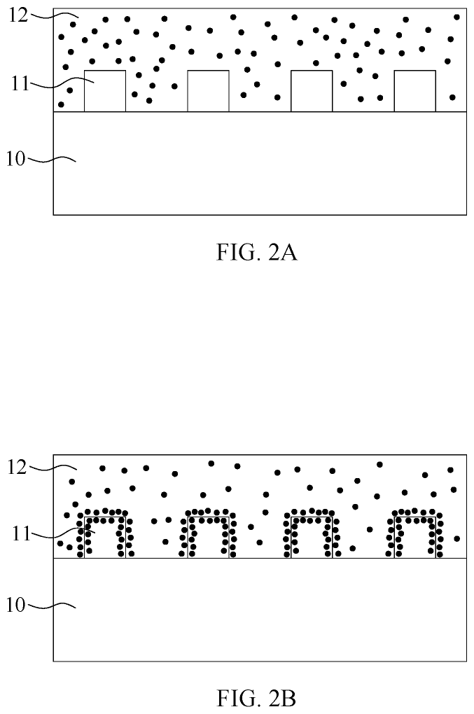

In accordance with the embodiments of FIG. 1, the patterned dielectric layer 11 partially covers the surface 101 of the substrate 10, the constituent or constituents in the semiconductor layer 12 may diffuse into the patterned dielectric layer 11 instead of substrate 10 (as shown in FIG. 2B). For example, Al in the semiconductor layer 12 may diffuse into the patterned dielectric layer 11 and stop or remain in the patterned dielectric layer 11. Therefore, the patterned dielectric layer 11 according to the present disclosure can prevent the constituent or constituents in the semiconductor layer 12 from diffusing into the substrate 10. In some embodiments, with the patterned dielectric layer 11, the diffusion depth of Al in the substrate 10 may be less than about 10 nm. In some embodiments, the parasitic resistance of the substrate 10 may be about 2000 Ohm (Ω) to about 10000Ω. In some embodiments, the transmission loss in the substrate 10 may be less than 1 dB/mm. The diffusion profile of the constituent or constituents in the substrate 10, the patterned dielectric layer 11, and the semiconductor layer 12 will be described with respect to FIG. 2A and FIG. 2B.

Still referring to FIG. 1, the nitride semiconductor layer 13 may be disposed on the semiconductor layer 12. The nitride semiconductor layer 13 may include a group III nitride. The nitride semiconductor layer 13 may include, for example, but is not limited to, a compound of InₓAl_{y}Ga_{(1-x-y)}N, where x+y≤1. The nitride semiconductor layer 13 may include, for example, but is not limited to, a compound of Al_{y}Ga_{(1-y)}N, where y≤1. The nitride semiconductor layer 13 may include, for example, but is not limited to, gallium nitride (GaN). The nitride semiconductor layer 13 may include, for example, but is not limited to, aluminum nitride (AlN). The nitride semiconductor layer 13 may include, for example, but is not limited to, indium nitride (InN). In some embodiments, the thickness of the nitride semiconductor layer 13 may range from about 0.5 μm to about 10 μm.

The nitride semiconductor layer 14 may be disposed on the nitride semiconductor layer 13. The nitride semiconductor layer 14 may include a group III nitride. The nitride semiconductor layer 14 may include, for example, but is not limited to, a compound of InₓAl_{y}Ga_{(1-x-y)}N, where x+y≤1. The nitride semiconductor layer 14 may include, for example, but is not limited to, a compound of Al_{y}Ga_{(1-y)}N, where y≤1. The nitride semiconductor layer 14 may include, for example, but is not limited to, GaN. The nitride semiconductor layer 14 may include, for example, but is not limited to, AlN. The nitride semiconductor layer 14 may include, for example, but is not limited to, InN. The nitride semiconductor layer 14 may include, for example, but is not limited to, doped GaN, doped AlGaN, doped InGaN, or other doped group III nitrides. In some embodiments, the thickness of the nitride semiconductor layer 14 may range from about 10 nm to about 100 nm.

A heterogeneous interface can be formed between the nitride semiconductor layer 14 and the nitride semiconductor layer 13. The nitride semiconductor layer 14 may have a relatively greater band gap than the nitride semiconductor layer 13. For example, the nitride semiconductor layer 14 may include AlGaN, the AlGaN may have a band gap of about 4 eV, the nitride semiconductor layer 13 may include GaN, and GaN may have a band gap of about 3.4 eV.

In some embodiments, the nitride semiconductor layer 13 may function as or include an electron channel region (or channel layer). The channel region may include a two-dimensional electron gas (2DEG) region, which is generally available in a heterostructure. In the 2DEG region, the electron gas can move freely in a two-dimensional direction (or lateral direction), but is limited in the movement in another dimension (e.g. vertical direction). In some embodiments, the channel region can be formed within the nitride semiconductor layer 13. In some embodiments, the channel region can be formed adjacent to an interface between the nitride semiconductor layer 13 and the nitride semiconductor layer 14.

In some embodiments, the nitride semiconductor layer 14 may function as a barrier layer. For example, the nitride semiconductor layer 14 may function as a barrier layer provided on the nitride semiconductor layer 13.

The passivation layer 15 may be disposed on the nitride semiconductor layer 14. The passivation layer 15 may covers a portion of the conductive structures 16, 18a, 18b, or 18c. The passivation layer 15 may exposes another portion of the conductive structures 16, 18a, 18b, or 18c for electrical connections. In some embodiments, the passivation layers 15a, 15b, 15c, 15d, 15e, 15f may include the same material. Alternatively, the passivation layers 15a, 15b, 15c, 15d, 15e, 15f may include different materials. The passivation layers 15a, 15b, 15c, 15d, 15e, 15f may serve as an interlayer dielectric layer. The passivation layers 15a, 15b, 15c, 15d, 15e, 15f may include a dielectric material. The passivation layers 15a, 15b, 15c, 15d, 15e, 15f may include a nitride. The passivation layers 15a, 15b, 15c, 15d, 15e, 15f may include, for example, but not limited to, silicon nitride (Si₃N₄). The passivation layers 15a, 15b, 15c, 15d, 15e, 15f may include an oxide. The passivation layers 15a, 15b, 15c, 15d, 15e, 15f may include, for example, but not limited to, silicon oxide (SiO₂). The passivation layers 15a, 15b, 15c, 15d, 15e, 15f may include, for example, but not limited to, a composite layer of an oxide or a nitride, such as Al₂O₃/SiN, Al₂O₃/SiO₂, AlN/SiN, and AlN/SiO₂. In some embodiments, the numbers of the passivation layers in the semiconductor device structure 1 may be adjusted depending on the design requirements.

The conductive structure 18a may be disposed on the nitride semiconductor layer 14. The conductive structure 18a may serve as a through via. For example, the conductive structure 18a may penetrate the passivation layer 15a and contact a top surface of the nitride semiconductor layer 14. The conductive structure 18a may include gold (Au), palladium (Pd), titanium (Ti), tantalum (Ta), tungsten (W), aluminum (Al), cobalt (Co), copper (Cu), nickel (Ni), platinum (Pt), lead (Pb), molybdenum (Mo) and compounds thereof (such as, titanium nitride (TiN), tantalum nitride (TaN), other conductive nitrides, or conductive oxides), metal alloys (such as aluminum-copper alloy (Al—Cu)), or other suitable materials.

In some embodiments, a doped semiconductor layer (not shown in the figures) may be disposed between the nitride semiconductor layer 14 and the conductive structure 18a. The doped semiconductor layer may include a doped III-V material. In some embodiments, the doped semiconductor layer may include a p-type III-V group material. The doped semiconductor layer may include, for example, but not limited to, a p-type group III nitride, such as a p-type GaN, a p-type AlN, a p-type InN, a p-type AlGaN, a p-type InGaN, or a p-type InAlN.

In some embodiments, the conductive structure 18a may function as a gate or a gate terminal. For example, the conductive structure 18a may be configured to control the channel region (or the 2DEG) in the nitride semiconductor layer 13. For example, the conductive structure 18a may be applied with a voltage to control the channel region in the nitride semiconductor layer 13. For example, the conductive structure 18a may be applied with a voltage to control the channel region in the nitride semiconductor layer 13 and below the conductive structure 18a. For example, the conductive structure 18a may be applied with a voltage to control the conduction between the conductive structure 18b and the conductive structure 18c.

The conductive structure 18b may be disposed on the nitride semiconductor layer 13. The conductive structure 18b may serve as a through via. For example, the conductive structure 18b may penetrate the passivation layer 15a and conduct a top surface of the nitride semiconductor layer 13. The conductive structure 18b may end at an interface between the nitride semiconductor layer 13 and the nitride semiconductor layer 14. In some embodiments, a portion of the conductive structure 18b may be located in the nitride semiconductor layer 13. In some embodiments, the conductive structure 18b may penetrate more layers of the passivation layer 15.

The conductive structure 18b may include a metal. In some embodiments, the conductive structure 18b may include, for example, but not limited to, Al, Ti, Pd, Ni, or W. In some embodiments, the conductive structure 18b may include a metal alloy. The conductive structure 18b may include, for example, but not limited to, TiN. In some embodiments, the conductive structure 18b may be or include a multi-layer structure. For example, the conductive structure 18b may include Ti, AlSi, Ti and TiN. In some embodiments, the conductive structure 18b may function as a source or a source terminal.

The conductive structure 18c may be disposed on the nitride semiconductor layer 13. The conductive structure 18c may serve as a through via. For example, the conductive structure 18c may penetrate the passivation layer 15a and conduct a top surface of the nitride semiconductor layer 13. The conductive structure 18c may end at an interface between the nitride semiconductor layer 13 and the nitride semiconductor layer 14. In some embodiments, a portion of the conductive structure 18c may be located in the nitride semiconductor layer 13. In some embodiments, the conductive structure 18c may penetrate more layers of the passivation layer 15.

The conductive structure 18c may include a metal. In some embodiments, the conductive structure 18c may include, for example, but not limited to, Al, Ti, Pd, Ni, or W. In some embodiments, the conductive structure 18c may include a metal alloy. The conductive structure 18c may include, for example, but not limited to, TiN. In some embodiments, the conductive structure 18c may be or include a multi-layer structure. For example, the conductive structure 18c may include Ti, AlSi, Ti and TiN. In some embodiments, the conductive structure 18c may function as a drain or a drain terminal.

The conductive structure 18b and the conductive structure 18c may be disposed between two opposite sides of the conductive structure 18a. Although the conductive structure 18b and the conductive structure 18c are respectively disposed on two opposite sides of the conductive structure 18a in FIG. 1, the conductive structure 18b, the conductive structure 18c, and the conductive structure 18a may have different configurations in other embodiments of the present disclosure due to the design requirements.

The conductive structure 16 may be disposed in the passivation layer 15. The conductive structure 16 may be electrically connected to the conductive structure 18b The conductive element 16 may include, for example, but is not limited to, one or more conductive layers, and one or more conductive vias. In some embodiments, the locations and/or numbers of the conductive elements in the semiconductor device structure 1 may be adjusted depending on the design requirements. The conductive structure 16 may include metal. The conductive structure 16 may include a metal compound. The conductive structure 16 may include, for example, but not limited to, Cu, tungsten carbide (WC), Ti, TiN, or Al—Cu.

The field plate 17 may be disposed in the passivation layer 15. The field plate 17 may be disposed on the passivation layer 15c. The field plate 17 may be covered by the passivation layer 15d. In some embodiments, the field plate 17 can be at zero potential. The field plate 17 can be connected to the conductive structure 18b (e.g., the source terminal), the conductive structure 18a (e.g., the gate terminal) and/or the conductive structure 18c (e.g., the drain terminal) through other conductor structures.

The field plate 17 can reduce the electric field between the gate terminal and the drain terminal. For example, the field plate 17 can reduce the electric field adjacent to the drain terminal. The field plate 17 can allow the electric field between the conductor structures (for example, the conductive structure 18a and the conductive structure 18c) to distribute evenly, improve the tolerance to voltage, and permit the voltage to release slowly, thereby improving the reliability of the semiconductor device structure 1. Although the drawing of the present disclosure depicts that the semiconductor device structure 1 has one field plate, the present disclosure is not limited thereto. In some embodiments, the semiconductor device structure 1 may include more field plates.

FIG. 2A illustrates diffusion distribution or diffusion profile of a constituent (for example, Al) from the semiconductor layer 12 before the semiconductor layer 12 is processed under a process condition (such as upon heating and/or pressurization). FIG. 2B illustrates diffusion distribution or diffusion profile of a constituent (for example, Al) from the semiconductor layer 12 after the semiconductor layer 12 is processed under a process condition (such as upon heating and/or pressurization). In some embodiments, FIG. 2A and FIG. 2B illustrate a part of the semiconductor device structure 1 in FIG. 1.

The dots in FIG. 2A and FIG. 2B may represent the concentration of the constituent. The density of the dots in FIG. 2A and FIG. 2B may be proportional to the concentration of the constituent.

For example, as illustrated in FIG. 2A, the semiconductor layer 12 may be an AlN layer, and Al may be evenly distributed in the semiconductor layer 12.

In FIG. 2B, Al may diffuse from the semiconductor layer 12 into the patterned dielectric layer 11 upon heating (such as under a temperature exceeding about 1000° C.). Al in the patterned dielectric layer 11 may be graded. For example, the Al concentration in the patterned dielectric layer 11 is greater in the boundary portion than in the central portion.

The Al concentration in the patterned dielectric layer 11 may be greater than the Al concentration in the substrate 10. For example, the atomic weight percentage of Al in the patterned dielectric layer 11 may be greater than the atomic weight percentage of Al in the substrate 10. In some embodiments, the ratio of the Al concentration in the patterned dielectric layer 11 to the Al concentration in the substrate 10 may be about 1.1 to about 2.0.

In some embodiments, the semiconductor layer 12 may be a graded layer having graded concentrations of Al. In some embodiments, the semiconductor layer 12 may be a superlattice layer having alternating AlGaN layers and AlN layers. The concentration variation of Al may be gradual or stepwise in several layers.

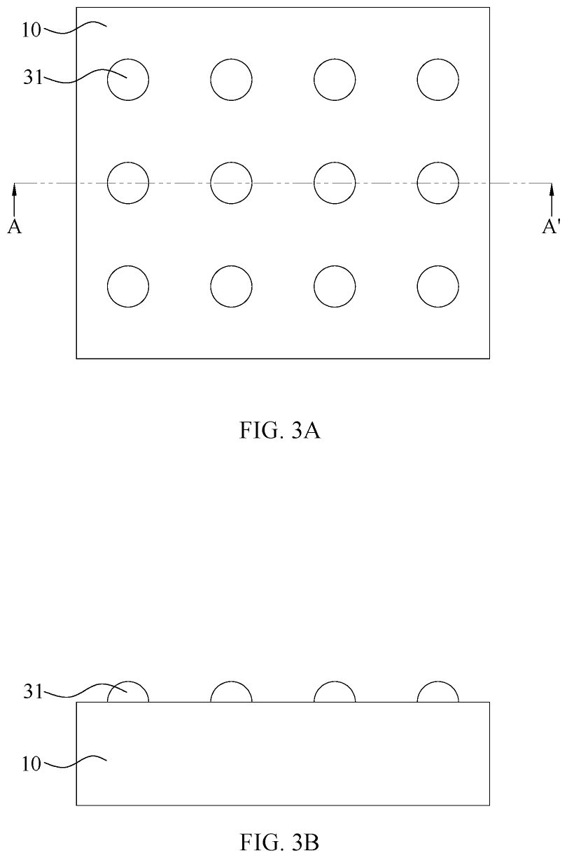

FIG. 3A is a top view of a patterned dielectric layer 31 in accordance with some embodiments of the present disclosure. FIG. 3B is a cross-sectional view of the patterned dielectric layer 31 cut along the line AA′ in FIG. 3A. In some embodiments, the patterned dielectric layer 11 in FIG. 1 may be replaced with the patterned dielectric layer 31 in FIG. 3A and FIG. 3B.

The patterned dielectric layer 31 may have a plurality of sublayers or islands arranged on the substrate 10 in a rectangular array. Each sublayer of the patterned dielectric layer 31 may have an arc shape from a side view.

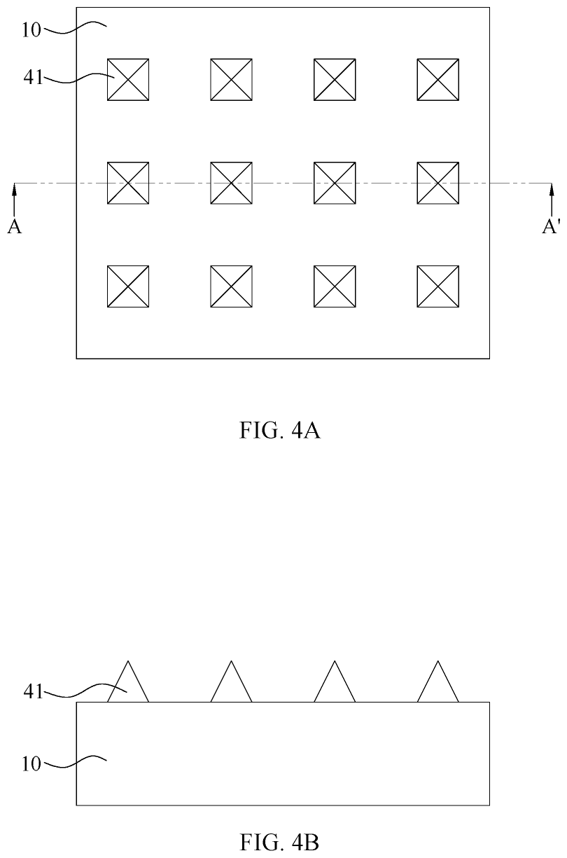

FIG. 4A is a top view of a patterned dielectric layer 41 in accordance with some embodiments of the present disclosure. FIG. 4B is a cross-sectional view of the patterned dielectric layer 41 cut along the line AA′ in FIG. 4A. In some embodiments, the patterned dielectric layer 11 in FIG. 1 may be replaced with the patterned dielectric layer 41 in FIG. 4A and FIG. 4B.

The patterned dielectric layer 41 may have a plurality of sublayers or islands arranged on the substrate 10 in a rectangular array. Each sublayer of the patterned dielectric layer 41 may have an triangle shape from a side view. Each of the sublayers of the patterned dielectric layer 41 may be an isosceles triangle, an equilateral triangle, an acute triangle, an obtuse triangle, or a right-angled triangle.

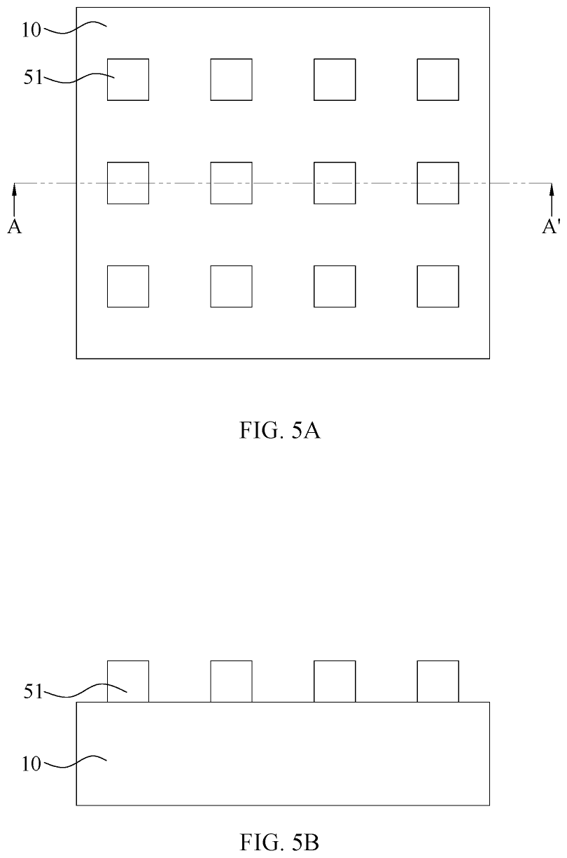

FIG. 5A is a top view of a patterned dielectric layer 51 in accordance with some embodiments of the present disclosure. FIG. 5B is a cross-sectional view of the patterned dielectric layer 51 cut along the line AA′ in FIG. 5A. In some embodiments, the patterned dielectric layer 11 in FIG. 1 may be replaced with the patterned dielectric layer 51 in FIG. 5A and FIG. 5B.

The patterned dielectric layer 51 may have a plurality of sublayers or islands arranged on the substrate 10 in a rectangular array. Each sublayer of the patterned dielectric layer 51 may have an rectangular shape from a side view.

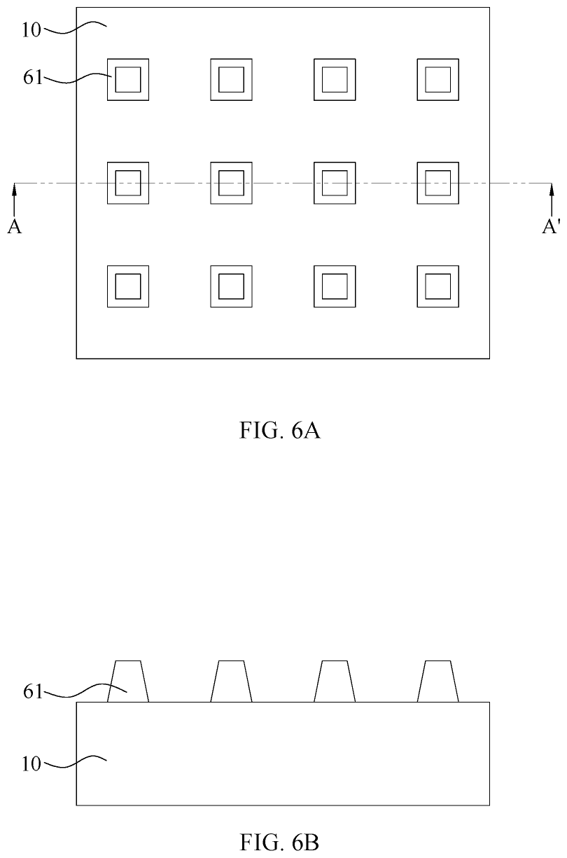

FIG. 6A is a top view of a patterned dielectric layer 61 in accordance with some embodiments of the present disclosure. FIG. 6B is a cross-sectional view of the patterned dielectric layer 61 cut along the line AA′ in FIG. 6A. In some embodiments, the patterned dielectric layer 11 in FIG. 1 may be replaced with the patterned dielectric layer 61 in FIG. 6A and FIG. 6B.

The patterned dielectric layer 61 may have a plurality of sublayers or islands arranged on the substrate 10 in a rectangular array. Each sublayer of the patterned dielectric layer 61 may have a trapezoid shape from a side view.

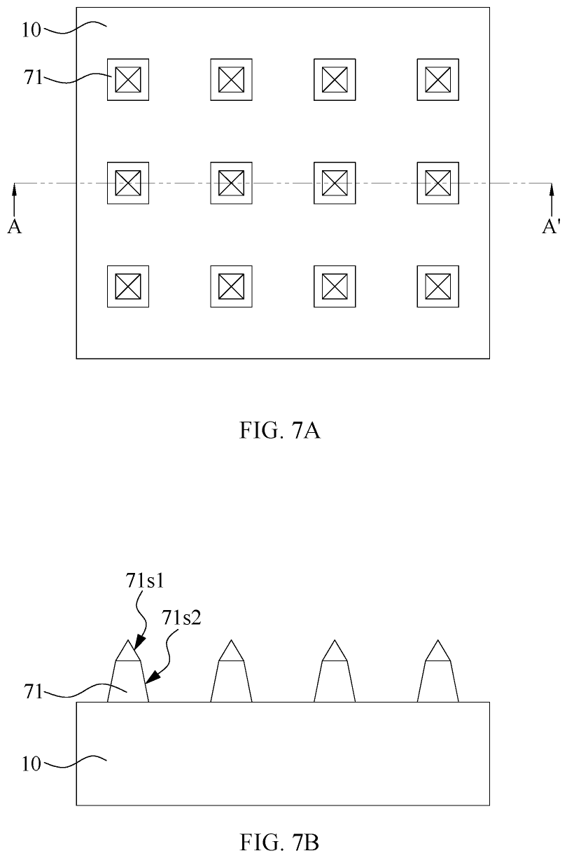

FIG. 7A is a top view of a patterned dielectric layer 71 in accordance with some embodiments of the present disclosure. FIG. 7B is a cross-sectional view of the patterned dielectric layer 71 cut along the line AA′ in FIG. 7A. In some embodiments, the patterned dielectric layer 11 in FIG. 1 may be replaced with the patterned dielectric layer 71 in FIG. 7A and FIG. 7B.

The patterned dielectric layer 71 may have a plurality of sublayers or islands arranged on the substrate 10 in a rectangular array. Each sublayer of the patterned dielectric layer 71 may have a first sidewall 71s1 and a second sidewall 71s2 connected with the first sidewall 71s1. The first sidewall 71s1 and the second sidewall 71s2 may have different slopes. The slope of the second sidewall 71s2 may be greater than the slope of the first sidewall 71s1.

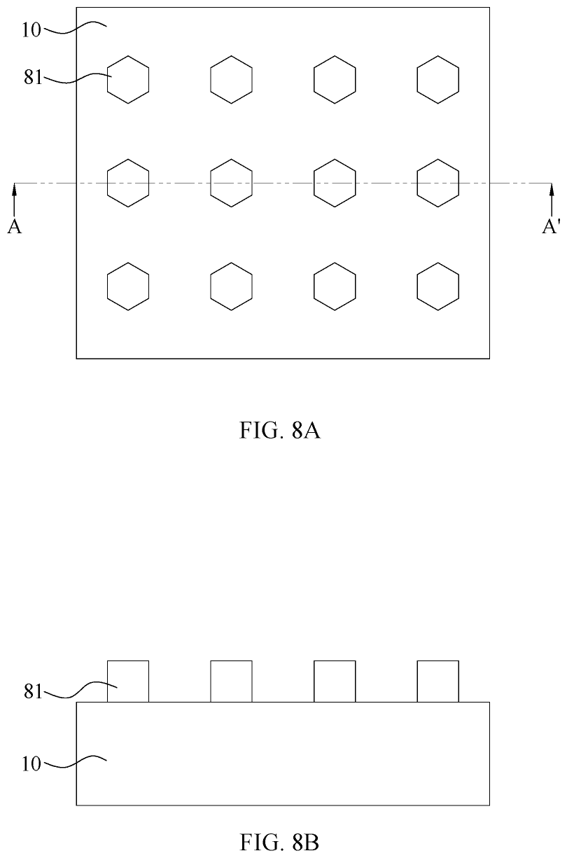

FIG. 8A is a top view of a patterned dielectric layer 81 in accordance with some embodiments of the present disclosure. FIG. 8B is a cross-sectional view of the patterned dielectric layer 81 cut along the line AA′ in FIG. 8A. In some embodiments, the patterned dielectric layer 11 in FIG. 1 may be replaced with the patterned dielectric layer 81 in FIG. 8A and FIG. 8B.

The patterned dielectric layer 81 may have a plurality of sublayers or islands arranged on the substrate 10 in a hexagonal array. Each sublayer of the patterned dielectric layer 81 may have six adjacent sidewalls.

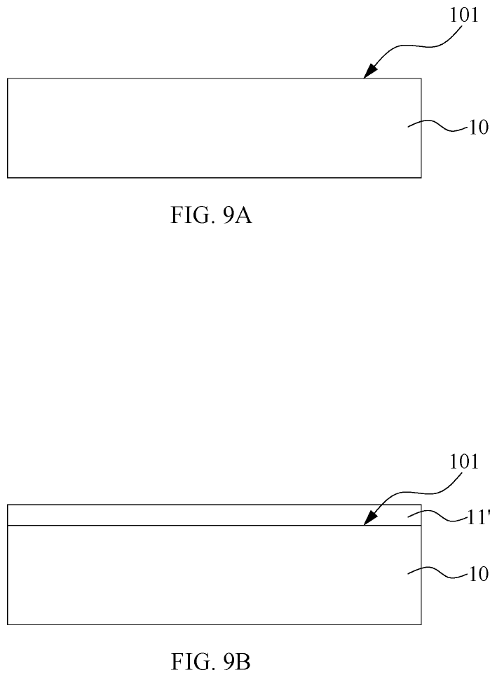

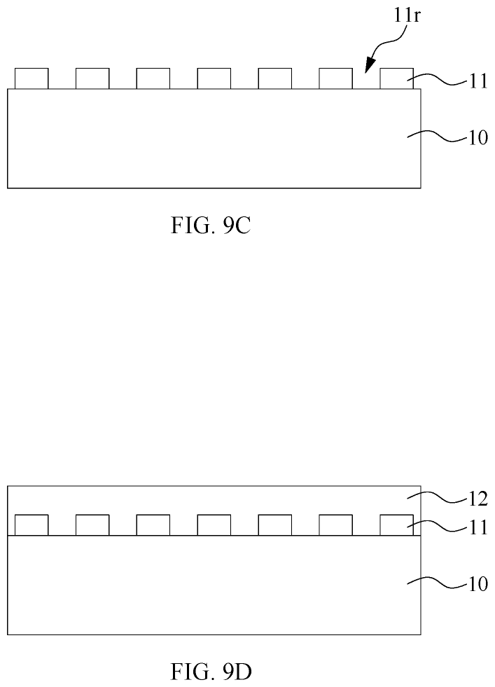

FIG. 9A, FIG. 9B, FIG. 9C, and FIG. 9D illustrate various stages of a method for manufacturing a semiconductor device structure in accordance with some embodiments of the present disclosure.

Referring to FIG. 9A, a substrate 10 may be provided. The substrate 10 may have a surface 101.

Referring to FIG. 9B, a dielectric layer 11′ may be disposed on the surface 101 of the substrate 10. The dielectric layer 11′ may include a thickness of about 0.5 μm to about 2.0 μm measured in a direction perpendicular to the surface 101. The dielectric layer 11′ may include, for example, but is not limited to, an amorphous dielectric material, such as silicon nitride, silicon oxide and silicon oxynitride. The dielectric layer 11′ may be formed by, for example, but is not limited to, thermal oxidation, plasma enhanced chemical vapor deposition (PECVD), or high density plasma CVD (HDPCVD).

Referring to FIG. 9C, the dielectric layer 11′ is patterned to form a plurality of sublayers or islands separate from each other. A plurality of vias or recesses 11r are formed in the patterned dielectric layer 11. A portion of the surface 101 of the substrate 10 may be exposed from the vias 11r. For example, about 15% to about 50% of the surface 101 of the substrate 10 may be exposed from the vias 11r. The percentage of total area coverage of the patterned dielectric layer 11 on the substrate 10 may be between about 50% and about 85%. The thickness t, the width w, and the spacing s may be referred to in FIG. 1.

The patterning process may include the following operations: forming a photoresist or mask on the dielectric layer 11′; defining a predetermined pattern on the photoresist by, for example, a lithographic technique; etching the dielectric layer 11′ through the patterned photoresist; and removing the photoresist.

Referring to FIG. 9D, a semiconductor layer 12 may be formed on the substrate 10 to cover the patterned dielectric layer 11. The semiconductor layer 12 may be formed by, for example, but is not limited to, metal organic CVD (MOCVD), metal organic vapor phase epitaxy (MOVPE), plasma enhanced CVD (PECVD), remote plasma enhanced CVD (RP-CVD), epitaxial growth, or other suitable operations. The epitaxial growth process may include molecular beam epitaxy (MBE), hydride vapor phase epitaxy (HYPE), chloride vapor-phase epitaxy (Cl-VPE), and liquid phase epitaxy (LPE). The semiconductor layer 12 may be formed at a temperature from about 1000° C. to about 1200° C.

Then, a nitride semiconductor layer (such as the nitride semiconductor layer 13 and/or nitride semiconductor layer 14 in FIG. 1) may be formed on the semiconductor layer 12 by, for example, but is not limited to, MOCVD, epitaxial growth, or other suitable operations. One or more passivation layers (such as the passivation layer 15 in FIG.) may be formed on the nitride semiconductor layer by, for example, but is not limited to, CVD, high density plasma (HDP) CVD, spin-on, sputtering, or other suitable operations. Electrodes, such as the source S, the drain D, and the gate G in FIG. 1 may be formed by for example, but is not limited to, dry etching or wet etching the passivation layers to form one or more openings and depositing materials (such as conductive materials) in the openings. In some embodiments, conductive materials can be formed by physical vapor deposition (PVD), CVD, atomic layer deposition (ALD), plating, and/or other suitable deposition steps. One or more conductive elements (such as the conductive element 16 in FIG. 1) and one or more field plates (such as the field plate 17 in FIG. 1) may be formed by for example, but is not limited to, dry etching or wet etching the passivation layers to form one or more openings and depositing materials (such as conductive materials) in the openings. The structure formed through the above operations may be similar to the semiconductor device structure 1 in FIG. 1.

As used herein, spatially relative terms, such as “beneath,” “below,” “lower,” “above,” “upper,” “lower,” “left,” “right” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 80 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As used herein, the terms “approximately,” “substantially,” “substantial” and “about” are used to describe and account for small variations. When used in conjunction with an event or circumstance, the terms can refer to instances in which the event of circumstance occurs precisely as well as instances in which the event or circumstance occurs to a close approximation. As used herein with respect to a given value or range, the term “about” generally refers to within ±10%, ±5%, ±1%, or ±0.5% of the given value or range. Ranges can be expressed herein as from one endpoint to another endpoint or between two endpoints. All ranges disclosed herein are inclusive of the endpoints, unless specified otherwise. The term “substantially coplanar” can refer to two surfaces within micrometers (μm) of lying along a same plane, such as within 10 μm, within 5 μm, within 1 μm, or within 0.5 μm of lying along the same plane. When referring to numerical values or characteristics as “substantially” the same, the term can refer to the values lying within ±10%, ±5%, ±1%, or ±0.5% of an average of the values.

The foregoing outlines features of several embodiments and detailed aspects of the present disclosure. The embodiments described in the present disclosure may be readily used as a basis for designing or modifying other processes and structures for carrying out the same or similar purposes and/or achieving the same or similar advantages of the embodiments introduced herein. Such equivalent constructions do not depart from the spirit and scope of the present disclosure, and various changes, substitutions, and alterations may be made without departing from the spirit and scope of the present disclosure.

What is claimed is:

1. A semiconductor device structure, comprising:
a substrate;
a semiconductor layer on the substrate;
a patterned dielectric layer disposed on the substrate and covered by the semiconductor layer, wherein the patterned dielectric layer is configured to prevent a constituent in the semiconductor layer from diffusing into the substrate;
a first nitride semiconductor layer on the semiconductor layer; and
a second nitride semiconductor layer on the first nitride semiconductor layer, wherein a band gap of the second nitride semiconductor layer is greater than a band gap of the first nitride semiconductor layer.

2. The semiconductor device structure of claim 1, wherein the constituent includes aluminum (Al).

3. The semiconductor device structure of claim 1, wherein the semiconductor layer includes Al_{X}Ga_{(1-X)}N, wherein 0.5≤X≤1.

4. The semiconductor device structure of claim 1, wherein an Al concentration in the patterned dielectric layer is greater than an Al concentration in the substrate.

5. The semiconductor device structure of claim 4, wherein the Al concentration in the patterned dielectric layer is graded.

6. The semiconductor device structure of claim 1, wherein a percentage of total area coverage of the patterned dielectric layer on the substrate is between about 50 percent (%) and about 85%.

7. The semiconductor device structure of claim 1, wherein the patterned dielectric layer includes a plurality of sublayers separating from each other, and each of the sublayers includes an arc shape.

8. The semiconductor device structure of claim 1, wherein the patterned dielectric layer includes a plurality of sublayers separating from each other, and each of the sublayers includes a triangle shape.

9. The semiconductor device structure of claim 1, wherein the patterned dielectric layer includes a plurality of sublayers separating from each other, and each of the sublayers includes a trapezoid shape.

10. The semiconductor device structure of claim 1, wherein the patterned dielectric layer includes a plurality of sublayers separating from each other, and each of the sublayers includes a first sidewall and a second sidewall connected with the first sidewall, wherein the first sidewall and the second sidewall have different slopes.

11. A semiconductor device structure, comprising:
a substrate;
a semiconductor layer on the substrate;
a patterned dielectric layer disposed on the substrate and covered by the semiconductor layer, wherein a percentage of total area coverage of the patterned dielectric layer on the substrate is between about 50 percent (%) and about 85%;
a first nitride semiconductor layer on the semiconductor layer; and
a second nitride semiconductor layer on the first nitride semiconductor layer, wherein a band gap of the second nitride semiconductor layer is greater than a band gap of the first nitride semiconductor layer.

12. The semiconductor device structure of claim 12, wherein the semiconductor layer includes Al_{X}Ga_{(1-X)}N, wherein 0.5≤X≤1.

13. The semiconductor device structure of claim 12, wherein an Al concentration in the patterned dielectric layer is greater than an Al concentration in the substrate.

14. The semiconductor device structure of claim 14, wherein the Al concentration in the patterned dielectric layer is graded.

15. The semiconductor device structure of claim 12, wherein a transmission loss of the substrate is less than 1 dB/mm.

16. The semiconductor device structure of claim 12, wherein the patterned dielectric layer includes a plurality of sublayers separating from each other, and each of the sublayers includes an arc shape.

17. The semiconductor device structure of claim 12, wherein the patterned dielectric layer includes a plurality of sublayers separating from each other, and each of the sublayers includes a triangle shape.

18. The semiconductor device structure of claim 12, wherein the patterned dielectric layer includes a plurality of sublayers separating from each other, and each of the sublayers includes a trapezoid shape.

19. The semiconductor device structure of claim 12, wherein the patterned dielectric layer includes a plurality of sublayers separating from each other, and each of the sublayers includes a first sidewall and a second sidewall connected with the first sidewall, wherein the first sidewall and the second sidewall have different slopes.

20. A method for manufacturing a semiconductor device structure, comprising:
providing a substrate having a surface;
depositing a dielectric layer on the surface of the substrate; and
patterning the dielectric layer to form a plurality of vias through the dielectric layer,
wherein about 15% to about 50% of the surface of the substrate is exposed from the plurality of vias.
